(19) United States
(12) Patent Application Publication
(10) Pub. No.: US 2026/0323851 A1
(43) Pub. Date: Oct. 15, 2026

(54) DISPLAY DEVICE, ELECTRONIC DEVICE INCLUDING THE SAME, AND METHOD OF MANUFACTURING DISPLAY DEVICE

(71) Applicant: Samsung Display Co., LTD., Yongin-si (KR)

(72) Inventor: SEDAE KI, Yongin-si (KR)

(21) Appl. No.: 19/535,048

(22) Filed: Feb. 10, 2026

(30) Foreign Application Priority Data
Apr. 14, 2025 (KR) 10-2025-0048369

(51) Int. Cl. H05K 5/03

(52) U.S. Cl. CPC H05K 5/03

(57) ABSTRACT

A display device includes a display panel, a cover panel disposed on a rear surface of the display panel, and an integrated chip electrically connected to the display panel and disposed on a rear surface of the cover panel. At least one groove is defined in the rear surface of the cover panel, the integrated chip overlaps the at least one groove in a plan view, and a partial area of the at least one groove does not overlap the integrated chip on the rear surface of the cover panel in the plan view.

### CROSS-REFERENCE TO RELATED APPLICATION

This application claims priority to Korean Patent Application No. 10-2025-0048369, filed on Apr. 14, 2025, and all the benefits accruing therefrom under 35 U.S.C. §119, the content of which in its entirety is herein incorporated by reference.

### BACKGROUND

Embodiments of the present disclosure described herein relate to a display device, an electronic device including the same, and a method of manufacturing a display device, and more particularly, relate to a display device including a cover panel that improves heat generation, an electronic device including the same, and a method of manufacturing a display device.

As performance of a display device, such as high quality and a high scanning rate is improved, heat generated therein is increasing. In particular, in the case of self-luminous displays such as organic light emitting diodes (OLEDs), heat is generated in thin film transistors (TFTs) for driving a pixel, backplane circuits, and other electronic components, and thus there is a possibility that brightness uniformity of a display is reduced, a burn-in phenomenon occurs, a panel is damaged, and a product lifetime is shortened.

For effective heat management, a heat dissipation structure for efficiently dissipating heat is desirable inside the display.

### SUMMARY

Embodiments of the present disclosure provide a display device having an improved heat dissipation effect.

Embodiments of the present disclosure also provide an electronic device including the display device.

Embodiments of the present disclosure also provide a method of manufacturing a display device having an improved heat dissipation effect.

According to an embodiment, a display device includes a display panel, a cover panel disposed on a rear surface of the display panel, and an integrated chip electrically connected to the display panel and disposed on a rear surface of the cover panel, where at least one groove is defined in the rear surface of the cover panel, the integrated chip overlaps the at least one groove in a plan view, and a partial area of the at least one groove does not overlap the integrated chip on the rear surface of the cover panel in the plan view.

The at least one groove may provide an air path.

The at least one groove may be provided as a plurality of grooves, and the plurality of grooves may be spaced apart from each other.

The at least one groove may be provided as a plurality of grooves, the plurality of grooves may include first grooves and second grooves spaced apart from the first grooves, and a separation distance between the first grooves and the second grooves may be greater than a separation distance between two adjacent grooves of the first grooves.

The integrated chip may include a timing controller overlapping the first grooves and a power management integrated chip overlapping the second grooves in the plan view.

The display device may further include a printed circuit board electrically connected to the display panel, where the integrated chip may be disposed on the printed circuit board, the printed circuit board may be disposed on the rear surface of the cover panel to overlap the at least one groove in the plan view, and a partial area of the at least one groove may not overlap the printed circuit board on the rear surface of the cover panel in the plan view.

The cover panel may include a cushion layer and a metal layer spaced further apart from the display panel than the cushion layer, and the at least one groove may be defined in the metal layer.

The metal layer may include aluminum (Al).

The cover panel may include a first area in which the at least one groove is defined and a second area around the first area, and a portion of the first area outside the at least one groove may have a greater thickness than a thickness of the second area.

According to an embodiment, an electronic device includes a display device and a processor, which controls the display device, where the display device includes a display panel, a cover panel disposed on a rear surface of the display panel, a printed circuit board electrically connected to the display panel and disposed on a rear surface of the cover panel, and at least one integrated chip mounted on the printed circuit board, at least one concave area is defined in the rear surface of the cover panel, the printed circuit board overlaps the at least one concave area in a plan view, and a partial area of the at least one concave area is exposed from the printed circuit board on the rear surface of the cover panel in the plan view.

The concave area may be an empty space.

The printed circuit board may include a main circuit board and a connection circuit board, the main circuit board may be disposed on the rear surface of the cover panel, and the connection circuit board may electrically connect the main circuit board to the display panel.

The at least one integrated chip may be mounted on the main circuit board, and the at least one integrated chip may overlap the concave area in the plan view.

The cover panel may include a cushion layer and a metal layer spaced further apart from the display panel than the cushion layer, and the at least one concave area may be defined in the metal layer.

The electronic device may be an electronic device for a vehicle.

According to an embodiment, a method of manufacturing a display device includes providing a preliminary display device including a display panel, a printed circuit board electrically connected to the display panel, and a cover panel which is disposed on a rear surface of the display panel and in which at least one groove is defined on a rear surface thereof and arranging the printed circuit board on the rear surface of the cover panel to overlap the at least one groove in a plan view, where a partial area of the at least one groove is exposed from the printed circuit board on the rear surface of the cover panel in the plan view.

The providing of the preliminary display device may include removing a release paper, in which a convex part is defined, from the cover panel.

The cover panel may include a first area in which the at least one groove is defined and a second area around the first area, the second area may have a smaller thickness than a thickness a portion of the first area outside the at least one groove, and a thickness of a portion of the release paper, which is attached to the second area of the cover panel, may be greater than a thickness of a portion of the release paper, which is attached to the portion of the first area of the cover panel outside the at least one groove.

A sum of the thicknesses of the cover panel and the release paper may be constant.

The providing of the preliminary display device may include preparing a preliminary cover panel, arranging a jig, in which a convex part is formed, on a rear surface of the preliminary cover panel, forming the cover panel, in which the at least one groove is defined, by pressing the jig to the preliminary cover panel, and attaching the cover panel, the display panel, and the printed circuit board electrically connected to the display panel.

### BRIEF DESCRIPTION OF THE FIGURES

The above and other objects and features of the present disclosure will become apparent by describing in detail embodiments thereof with reference to the accompanying drawings.

FIG. 1 is a block diagram of an electronic device according to an embodiment.

FIG. 2 is a schematic view of the electronic device according to an embodiment.

FIG. 3 is a perspective view of a display device according to an embodiment of the present disclosure.

FIG. 4A is a rear plan view of the display device before a printed circuit board is bent according to an embodiment of the present disclosure.

FIG. 4B is a cross-sectional view taken along line I-I' in FIG. 4A.

FIG. 5 is a rear plan view of the display device after a printed circuit board is bent according to an embodiment of the present disclosure.

FIGS. 6A to 6D are cross-sectional views illustrating a method of manufacturing a display device according to an embodiment of the present disclosure.

FIGS. 7A to 7D are cross-sectional views illustrating the method of manufacturing a display device according to an embodiment of the present disclosure.

FIG. 8 is a rear view illustrating a cover panel according to an embodiment of the present disclosure.

### DETAILED DESCRIPTION

In the specification, the expression that a first component (or an area, a layer, a part, a portion, etc.) is “disposed on”, “connected with” or “coupled to” a second component means that the first component is directly disposed on/connected with/coupled to the second component or means that a third component is interposed therebetween.

In the detailed description and the accompanying drawings, the same reference numerals refer to the same components. Further, in the drawings, the thickness, the ratio, and the dimension of components are exaggerated for effective description of technical contents. The term “and/or” includes all combinations of one or more components that may be defined by associated components.

Although the terms “first,” “second,” etc., may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, "comprise", "have", etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the present disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

Hereinafter, an embodiment of the present disclosure will be described with reference to the accompanying drawings.

A display device according to an embodiment may be applied to various electronic devices. An electronic device according to an embodiment may include the above-described display device and may further include a module or device having other additional functions in addition to the display device.

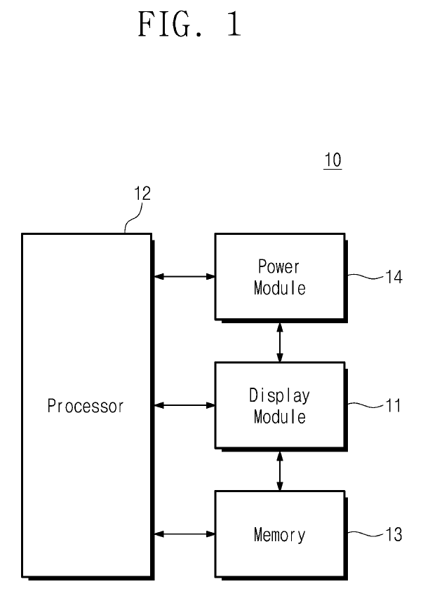

FIG. 1 is a block diagram of an electronic device according to an embodiment. Referring to FIG. 1, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information for operations of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device and a power conversion module that converts power supplied by the power supply module to generate power for the operation of the electronic device 10.

At least one of the components of the electronic device 10 may be included in the display device according to an embodiment. Further, some of individual modules functionally included inside one module may be included inside the display device, and the others thereof may be provided separately from the display device. For example, the display device may include the display module 11, and the processor 12, the memory 13, and the power module 14 may be provided in the form of other devices in the electronic device 10 rather than the display device.

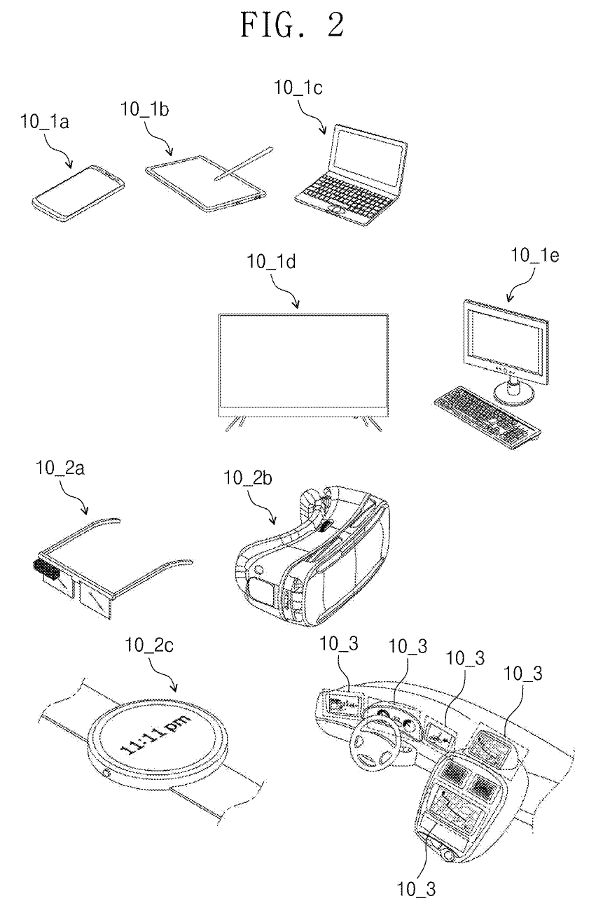

FIG. 2 is a schematic view of the electronic device according to an embodiment.

Referring to FIG. 2, various electronic devices to which the display device according to an embodiment is applied may include an image display electronic device such as a smartphone 10_1a, a tablet PC 10_1b, a laptop computer 10_1c, a television (TV) 10_1d, and a desk monitor 10_1e, a wearable electronic device including a display module such as a smart glasses 10_2a, a head mounted display 10_2b, and a smart watch 10_2c, and a vehicle electronic device 10_3 including a display module such as an instrument panel, a center fascia, a center information display (CID) disposed on a dashboard, and a room mirror display of a vehicle.

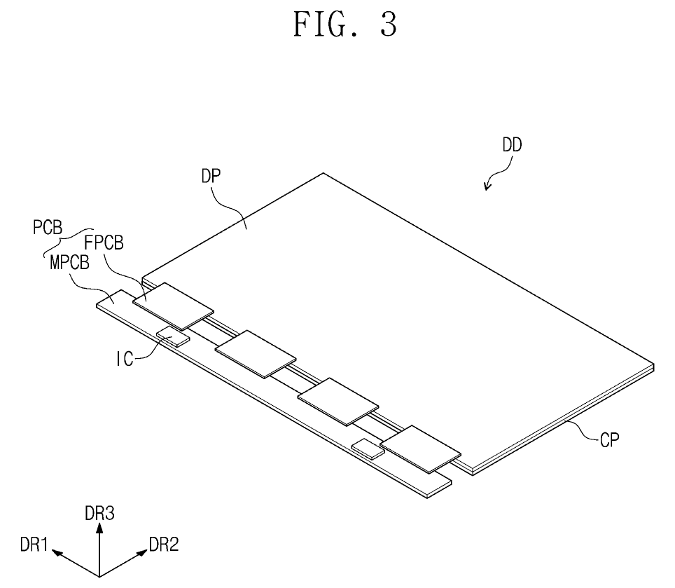

FIG. 3 is a perspective view of a display device according to an embodiment of the present disclosure.

Referring to FIG. 3, a display device DD may include a display panel DP, a printed circuit board PCB, an integrated chip IC, and a cover panel CP. Although not illustrated separately, the display device DD may further include a housing for accommodating the display device DD other than the above-described components.

The display panel DP may include a plurality of pixels. The pixels display light in response to an electrical signal. The light displayed by the pixels implements an image. The display panel DP may have a rectangular shape having long sides extending in a first direction DR1 and short sides extending in a second direction DR2 intersecting the first direction DR1. However, the present disclosure is not limited thereto, and the display panel DP may have various shapes such as a circular shape and a polygonal shape. Hereinafter, a direction substantially perpendicular to a plane defined by the first direction DR1 and the second direction DR2 is defined as a third direction DR3. In the specification, the meaning of "on a plane" is defined as a state of being viewed in the third direction DR3.

The printed circuit board PCB may include a connection printed circuit board FPCB and a main printed circuit board MPCB. The connection printed circuit board FPCB may electrically connect the main printed circuit board MPCB to the display panel DP. The connection printed circuit board FPCB may be formed of a flexible film.

The integrated chip IC may be electrically connected to the display panel DP to provide signals to the display panel DP. The integrated chip IC may be mounted on the printed circuit board PCB. In particular, the integrated chip IC may be mounted on the main printed circuit board MPCB. In an embodiment, two integrated chips IC are illustrated by way of example.

The integrated chip IC may be a component that performs display driving, data processing, connection interfaces, and the like, and may include a timing controller TCON, a display driver IC, a power management IC PMIC, and a touch controller IC. As the main printed circuit board MPCB is disposed in the cover panel CP, the integrated chip IC may be disposed on a rear surface of the cover panel CP.

The cover panel CP may be disposed on a rear surface of the display panel DP. The cover panel CP may absorb an external impact or discharge heat generated in other components to the outside.

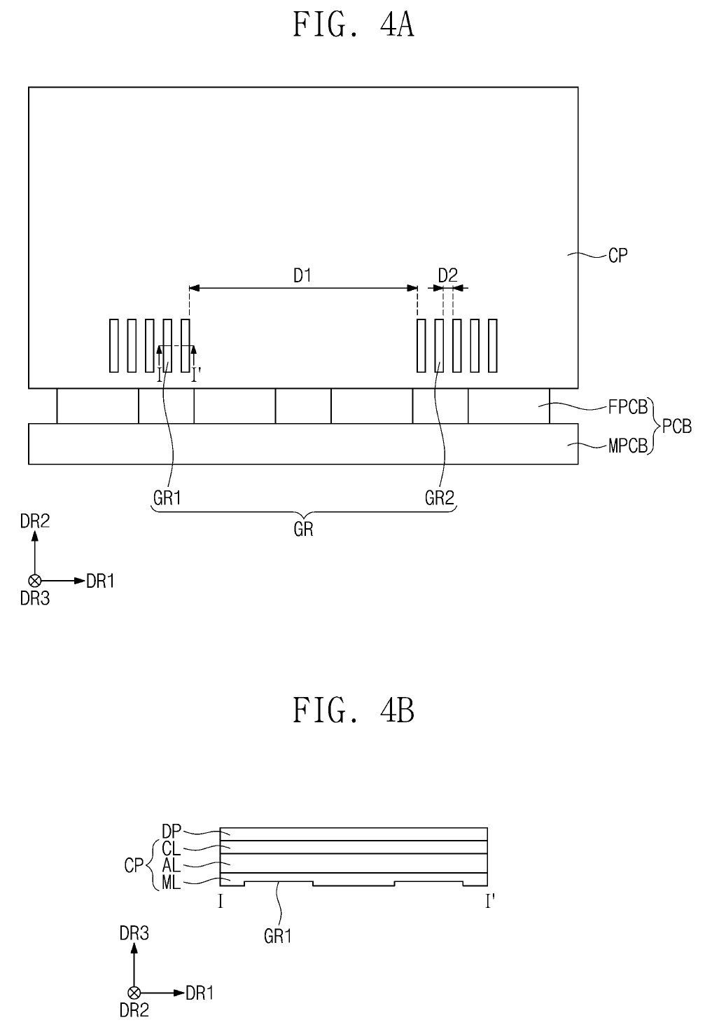

FIG. 4A is a rear plan view of the display device before a printed circuit board is bent according to an embodiment of the present disclosure. As used herein, the “plan view” of the display device is a view in a thickness direction (i.e., third direction DR3) of the display device.

Referring to FIG. 4A, at least one groove GR is defined in the rear surface of the cover panel CP. Referring to FIG. 4B, the groove GR may be formed in an engraved shape that is concavely cut in the cover panel CP. For this purpose, the groove GR may be defined (named) as a concave area. A concave portion of the groove GR may be filled with air in an empty state. That is, the groove GR may provide an air path filled with air. In the present disclosure, the air path may mean an air flow passage provided to discharge heat generated between two plates to the outside.

At least one groove GR may be provided as a plurality of grooves GR as illustrated in FIG. 4A. The plurality of grooves GR may be provided to improve a heat dissipation effect of the cover panel CP. The plurality of grooves GR may include first grooves GR1 and second grooves GR2 arranged to be spaced apart from the first grooves GR1. A separation distance D1 between the first grooves GR1 and the second grooves GR2 may be greater than a separation distance D2 between the first grooves GR1.

FIG. 4B is a cross-sectional view taken along line I-I' in FIG. 4A.

Referring to FIG. 4B, the cover panel CP may include a cushion layer CL, an adhesive layer AL, and a metal layer ML. The cushion layer CL provides an upper surface of the cover panel CP, the metal layer ML provides a lower surface of the cover panel CP, and the cover panel CP couples the cushion layer CL, the adhesive layer AL, and the metal layer ML. A separate adhesive layer (not illustrated) may be included in the cushion layer CL and the display panel DP.

The cushion layer CL absorbs an external impact. The cushion layer CL may include a plurality of protrusions protruding in the third direction DR3. The protrusions may have an embossed shape. The cushion layer CL may include the embossed protrusions protruding toward the display panel DP, thereby efficiently preventing a phenomenon in which components arranged on the rear surface of the display panel DP are reflected.

The metal layer ML discharges heat generated in other components to the outside. The metal layer ML may additionally include an electromagnetic wave (EMI) shielding function. The metal layer ML may be designed in a single metal layer or a composite metal structure, and may include aluminum (Al). The groove GR may be defined in the metal layer ML. FIG. 4B illustrates, by way of example, two grooves.

The adhesive layer AL may be a layer for connecting the cushion layer CL and the metal layer ML and may include an adhesive. As polyimide, an acryl-based adhesive, a silicone adhesive, or the like may be used for the adhesive layer AL.

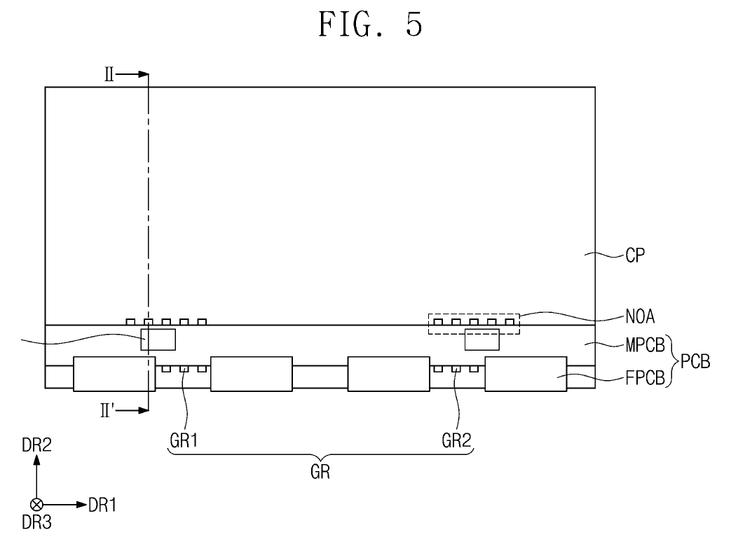

FIG. 5 is a rear plan view of the display device after a printed circuit board is bent according to an embodiment of the present disclosure.

FIG. 5 illustrates a state in which the connection printed circuit board FPCB is bent in the state of FIG. 4A and thus the main printed circuit board MPCB is located on the rear surface of the cover panel CP. The main printed circuit board MPCB may be attached/coupled to the metal layer ML (see FIG. 4B) by the adhesive layer (not illustrated).

FIG. 5 illustrates a case in which the connection printed circuit board FPCB may be bent and disposed on the cover panel CP, but the present disclosure is not limited thereto. For example, the display device DD may include a flexible display panel DP, and the display panel DP may be bent so that the main printed circuit board MPCB may be disposed on the cover panel CP.

The integrated chip IC may overlap the at least one groove GR, and a partial area of the at least one groove GR may not overlap the integrated chip IC on the rear surface of the cover panel CP in a plan view. The printed circuit board PCB may overlap the at least one concave area in a plan view, and a partial area of the at least one concave area may be exposed from the printed circuit board PCB on the rear surface of the cover panel CP.

According to an embodiment of the present disclosure, the integrated chip IC may be driven to generate heat. Accordingly, the main printed circuit board MPCB may also generate heat. A non-overlapping area NOA of the groove GR may be exposed from the main printed circuit board MPCB to emit the generated heat to the outside. The non-overlapping area NOA may include both ends of the groove GR.

The integrated chip IC may include a timing controller overlapping the first grooves GR1 and a power management integrated chip overlapping the second grooves GR2 in a plan view. The integrated chips IC may be arranged in the first grooves GR1 and the second grooves GR2. As an example, the first grooves GR1 may overlap the timing controller of the integrated chip IC, and the second grooves GR2 may overlap the power management IC of the integrated chip IC in a plan view. The location of the integrated chip IC disposed in the groove GR is not limited to the above example, and even when only some of the plurality of integrated chips IC overlap the groove GR in a plan view, a heat dissipation effect may be effectively improved.

Further, the drawing illustrates that the grooves GR are formed in the plurality of integrated chips IC, but the grooves GR may be formed in the entire main printed circuit board MPCB regardless of the location of the integrated chip IC.

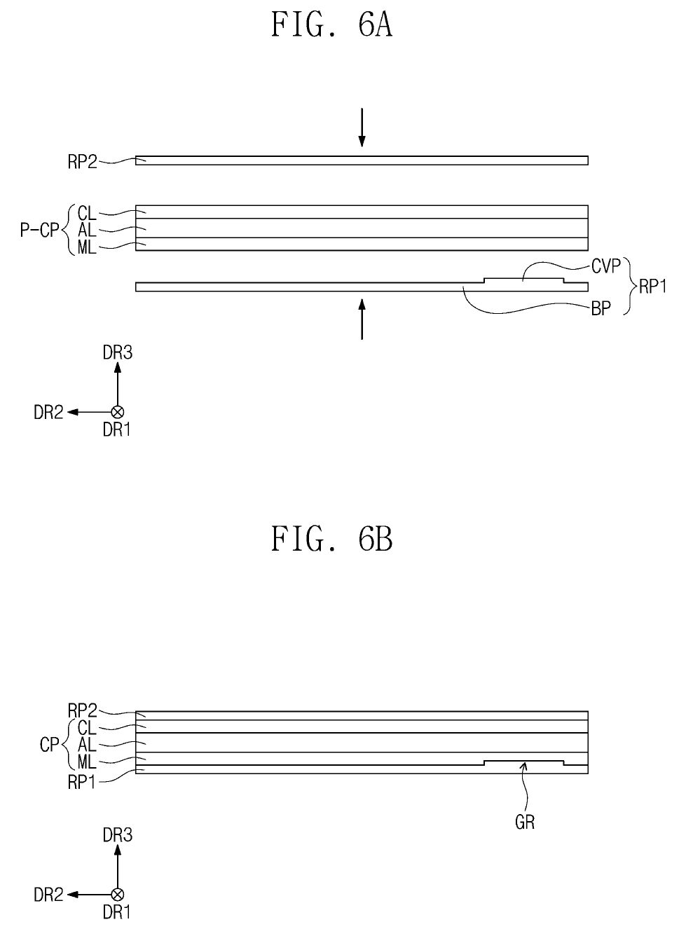

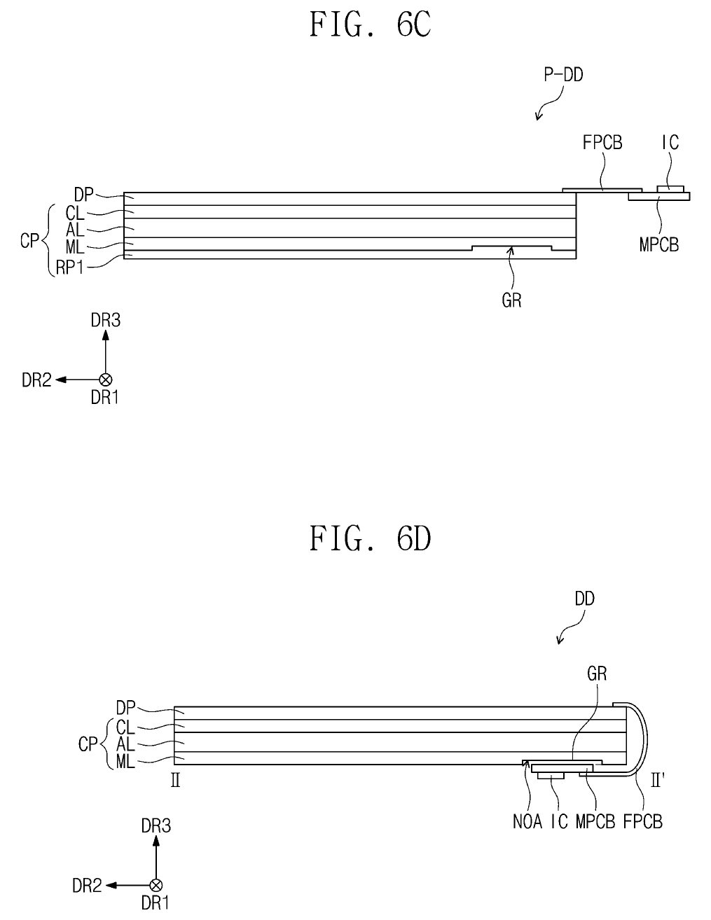

FIGS. 6A to 6D are cross-sectional views illustrating a method of manufacturing a display device according to an embodiment of the present disclosure. In description of FIGS. 6A to 6D, the same/similar components will be described using the same/similar reference numerals with reference to FIGS. 1 to 5, and duplicated descriptions thereof will be omitted.

Referring to FIG. 6A, a preliminary cover panel P-CP is provided. The preliminary cover panel P-CP means a cover panel in which the groove GR (see FIG. 6D) is not defined before the cover panel CP (see FIG. 6D) is manufactured.

A first release paper RP1 and a second release paper RP2 may be attached to upper and lower portions of the preliminary cover panel P-CP. The release paper may protect the cover panel CP (see FIG. 6B) and may prevent foreign substances from being attached to the cover panel CP (see FIG. 6B) during a processing and transportation operation. The first release paper RP1 may be attached to the metal layer ML of the preliminary cover panel P-CP, and the second release paper RP2 may be attached to the cushion layer CL of the preliminary cover panel P-CP.

The first release paper RP1 includes a base part BP and a convex part CVP defined on an upper surface of the base part BP. The base part BP is formed flat. The convex part CVP may have a shape in which an upper surface of the release paper RP protrudes in the third direction DR3. The convex part CVP may be defined to correspond to the location of the main printed circuit board MPCB (see FIG. 5) or the integrated chip IC (see FIG. 5).

A shape of the convex part CVP on a cross section is illustrated in a quadrangular shape but is not limited to an embodiment as long as the convex part CVP protrudes in the third direction DR3.

Referring to FIG. 6B, a rear surface of the preliminary cover panel P-CP is pressed in a state in which the first release paper RP1 is attached. During the pressing process, the groove GR having a shape corresponding to the convex part CVP of the first release paper RP1 is formed in the metal layer ML. The groove GR may be formed to be concave in the third direction DR3 from a surface of the metal layer ML. Referring to FIGS. 4A and 5, the groove GR defined in the rear surface of the cover panel CP may be formed as the plurality of grooves GR.

Referring to FIG. 6C, the second release paper RP2 is removed, the display panel DP is attached, and thus a preliminary display device P-DD is formed. The preliminary display device P-DD may be formed by pressing the cover panel CP. A process of pressing the cover panel CP may be performed through a roller.

Referring to FIG. 6D, the connection printed circuit board FPCB may be bent so that the main printed circuit board MPCB may be disposed on the rear surface of the cover panel CP. The main printed circuit board MPCB and the integrated chip IC are arranged in the groove GR. The groove GR may be formed to have a larger width than the main printed circuit board MPCB to include the main printed circuit board MPCB, the integrated chip IC, and the non-overlapping area NOA in a partial area. FIG. 6D corresponds to a cross-sectional view taken along line II-II’ in FIG. 5.

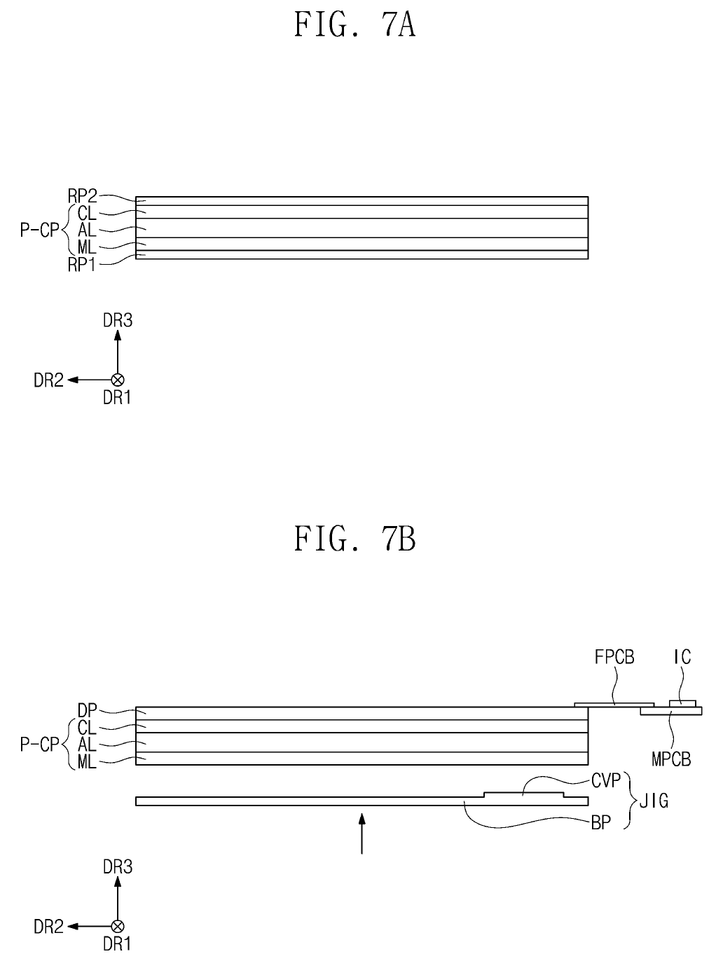

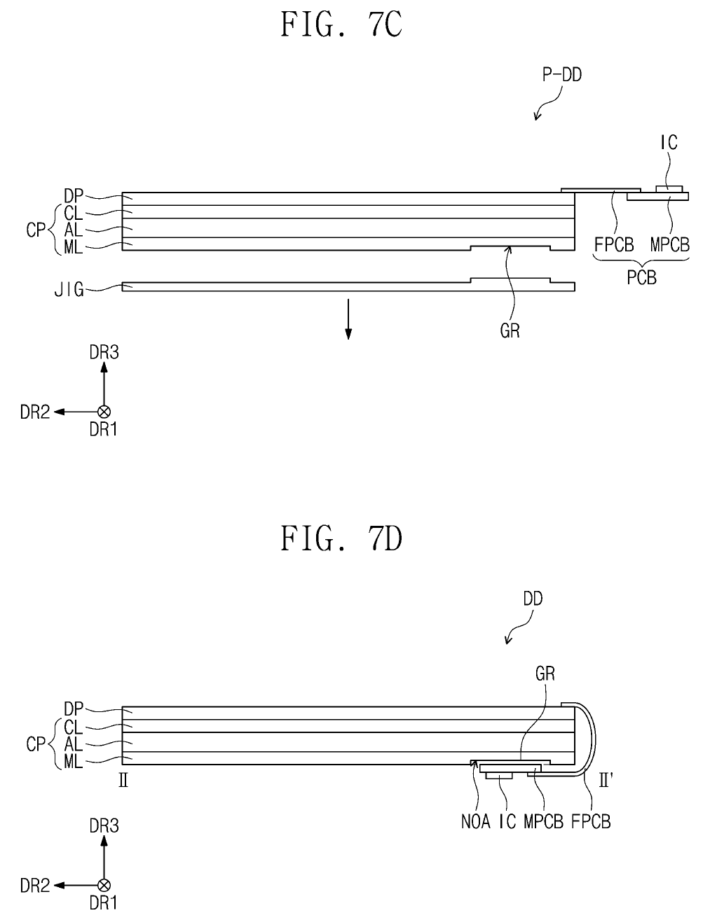

FIGS. 7A to 7C are cross-sectional views illustrating the method of manufacturing a display device according to an embodiment of the present disclosure. In description of FIGS. 7A to 7C, the same/similar components will be described using the same/similar reference numerals with reference to FIGS. 1 to 5, and duplicated descriptions thereof will be omitted.

Referring to FIG. 7A, the preliminary cover panel P-CP may be moved in a state in which the first release paper RP1 is attached to an lower portion thereof and the second release paper RP2 is attached to a upper portion thereof. Unlike the first release paper RP1of FIG. 6A, the second release paper RP2 of FIG. 7A may be flat without the separate convex part CVP.

Referring to FIG. 7B, in the preliminary cover panel P-CP, the second release paper RP2 (see FIG. 7A) is removed. Thereafter, the display panel DP may be attached to an upper surface of the preliminary cover panel P-CP. In the preliminary cover panel P-CP, the first release paper RP1 (see FIG. 7A) is removed. Thereafter, a jig JIG is disposed on the rear surface of the preliminary cover panel P-CP.

The jig JIG is used to form a shape of the cover panel CP. The jig JIG includes the base part BP and the convex part CVP defined on the upper surface of the base part BP. The base part BP is formed flat. The convex part CVP may have a shape in which the upper surface of the release paper RP protrudes in the third direction DR3. The jig JIG may be disposed on the rear surface of the cover panel CP such that a surface including the convex part CVP faces the cover panel CP. The jig JIG may be pressed in a direction of the cover panel CP. A process of pressing the jig JIG may be performed through a roller.

Referring to FIG. 7C, after the pressing, the jig JIG is removed from the cover panel CP. The metal layer ML of the cover panel CP has the groove GR having a shape corresponding to the convex part CVP. The groove GR is formed in a debossed shape. The preliminary display device P-DD including the cover panel CP in which the display panel DP, the printed circuit board PCB, and the groove GR are defined is provided.

Referring to FIG. 7D, the display device DD in which the main printed circuit board MPCB is disposed on the rear surface of the cover panel CP is provided. The connection printed circuit board FPCB may be bent so that the main printed circuit board MPCB may be disposed on the rear surface of the cover panel CP. The main printed circuit board MPCB and the integrated chip IC are arranged in the groove GR. The groove GR may include the non-overlapping area NOA that does not overlap the main printed circuit board MPCB and the integrated chip IC in a partial area in a plan view. The groove GR may be formed to have a width greater than a width of the main printed circuit board MPCB. FIG. 7D corresponds to a cross-sectional view taken along line II-II’ in FIG. 5.

In FIGS. 7A to 7D, a method of attaching the preliminary cover panel P-CP and the display panel DP and forming the groove GR has been described, but the present disclosure is not limited thereto. As an example, after the groove GR is formed by pressing the jig JIG on the preliminary cover panel P-CP, the cover panel CP and the display panel DP may be attached.

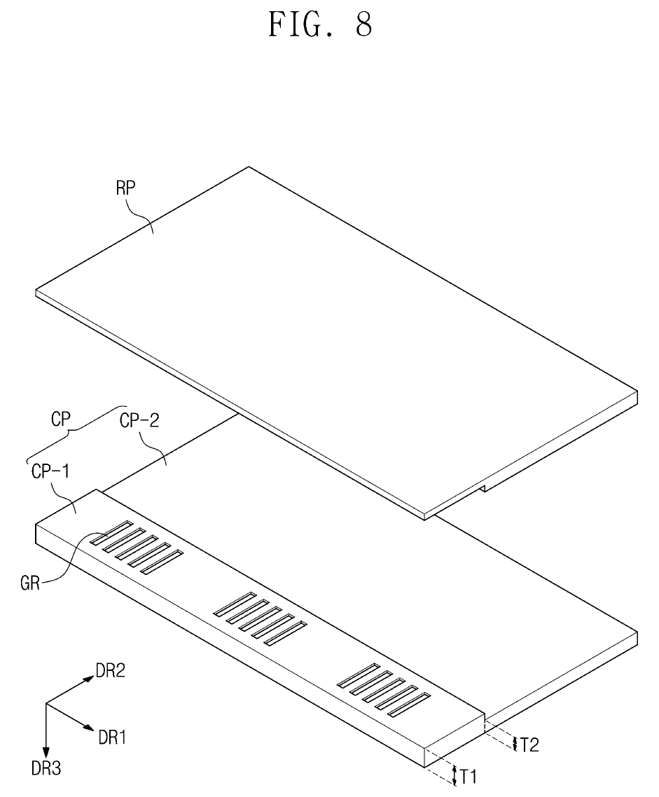

FIG. 8 is a rear view illustrating a cover panel according to an embodiment of the present disclosure.

According to an embodiment of the present disclosure, the cover panel CP may introduce all methods of increasing a thickness of an area in which the groove GR is formed. In this case, a layer of which a thickness is increased may be the metal layer ML (see FIG. 4B).

The cover panel CP may include a first area CP-1 in which the groove GR is defined and a second area CP-2 around the first area CP-1. The first area CP-1 is an area in which the printed circuit board PCB is disposed. The first area CP-1 may be more affected by heat emitted from the printed circuit board PCB as compared to the second area CP-2, and thus a temperature of the first area CP-1 may be further increased.

A thickness T1 of a portion of the first area CP-1 outside the groove GV may be greater than a thickness T2 of the second area CP-2. In this case, in the first area CP-1, the metal layer ML (see FIG. 4B) may have a greater thickness than in the second area CP-2.

The cover panel CP of FIG. 8 may manage heat emitted from the printed circuit board PCB (see FIG. 5) using the groove GR, may increase a thickness of the metal layer ML (see FIG. 4A) having high thermal conductivity, and thus may increase a heat dissipation effect.

The release paper RP provided to manufacture the cover panel CP of FIG. 8 has a thickness capable of compensating for a thickness of the cover panel CP. An area of the release paper RP attached to the first area CP-1 is formed to be thinner than an area of the release paper RP attached to the second area CP-2. The difference between the thicknesses of the release papers RP in the areas corresponds to a difference between the thickness T1 of the first area CP-1 of the cover panel CP and the thickness T2 of the second area CP-2 of the cover panel CP. The cover panel CP and the release paper RP are manufactured to have the same sum of the thicknesses as a whole, and thus when the cover panel CP is attached to the display panel DP by a lamination process, degradation of adhesion quality may be effectively prevented.

In a display device according to an embodiment of the present disclosure, an integrated chip having a high heat generation amount is disposed on a groove defined in a cover panel. The groove serves as a moving path for air, and thus heat generated from the integrated chip may be effectively discharged to the outside.

Although the description has been made above with reference to an embodiment of the present disclosure, the present disclosure is not limited to an embodiment and may be variously changed and modified within the spirit and scope of the present disclosure claimed below by those skilled in the art to which the present disclosure pertains.

What is claimed is:

1. A display device comprising:
a display panel;
a cover panel disposed on a rear surface of the display panel; and
an integrated chip electrically connected to the display panel and disposed on a rear surface of the cover panel,
wherein at least one groove is defined in the rear surface of the cover panel,
wherein the integrated chip overlaps the at least one groove in a plan view, and
wherein a partial area of the at least one groove does not overlap the integrated chip on the rear surface of the cover panel in the plan view.

2. The display device of claim 1, wherein the at least one groove provides an air path.

3. The display device of claim 1, wherein the at least one groove is provided as a plurality of grooves, and
wherein the plurality of grooves are spaced apart from each other.

4. The display device of claim 1, wherein the at least one groove is provided as a plurality of grooves,
wherein the plurality of grooves include first grooves and second grooves spaced apart from the first grooves, and
wherein a separation distance between the first grooves and the second grooves is greater than a separation distance between two adjacent grooves of the first grooves.

5. The display device of claim 4, wherein the integrated chip includes a timing controller overlapping the first grooves and a power management integrated chip overlapping the second grooves in the plan view.

6. The display device of claim 1, further comprising:
a printed circuit board electrically connected to the display panel,
wherein the integrated chip is disposed on the printed circuit board,
wherein the printed circuit board is disposed on the rear surface of the cover panel to overlap the at least one groove in the plan view, and
wherein a partial area of the at least one groove does not overlap the printed circuit board on the rear surface of the cover panel in the plan view.

7. The display device of claim 1, wherein the cover panel includes:
a cushion layer; and
a metal layer spaced further apart from the display panel than the cushion layer, and
wherein the at least one groove is defined in the metal layer.

8. The display device of claim 7, wherein the metal layer includes aluminum (Al).

9. The display device of claim 1, wherein the cover panel includes a first area in which the at least one groove is defined and a second area around the first area, and
wherein a portion of the first area outside the at least one groove has a greater thickness than a thickness of the second area.

10. An electronic device comprising:
a display device; and
a processor, which controls the display device,
wherein the display device includes:
a display panel;
a cover panel disposed on a rear surface of the display panel;
a printed circuit board electrically connected to the display panel and disposed on a rear surface of the cover panel; and
at least one integrated chip mounted on the printed circuit board,
wherein at least one concave area is defined in the rear surface of the cover panel,
wherein the printed circuit board overlaps the at least one concave area in a plan view, and
wherein a partial area of the at least one concave area is exposed from the printed circuit board on the rear surface of the cover panel in the plan view.

11. The electronic device of claim 10, wherein the concave area is an empty space.

12. The electronic device of claim 10, wherein the printed circuit board includes a main circuit board and a connection circuit board,
wherein the main circuit board is disposed on the rear surface of the cover panel, and
wherein the connection circuit board electrically connects the main circuit board to the display panel.

13. The electronic device of claim 12, wherein the at least one integrated chip is mounted on the main circuit board, and
wherein the at least one integrated chip overlaps the concave area in the plan view.

14. The electronic device of claim 10, wherein the cover panel includes:
a cushion layer; and
a metal layer spaced further apart from the display panel than the cushion layer, and
wherein the at least one concave area is defined in the metal layer.

15. The electronic device of claim 10, wherein the electronic device is an electronic device for a vehicle.

16. A method of manufacturing a display device, the method comprising:
providing a preliminary display device including a display panel, a printed circuit board electrically connected to the display panel, and a cover panel which is disposed on a rear surface of the display panel and in which at least one groove is defined on a rear surface thereof; and
arranging the printed circuit board on the rear surface of the cover panel to overlap the at least one groove in a plan view,
wherein a partial area of the at least one groove is exposed from the printed circuit board on the rear surface of the cover panel in the plan view.

17. The method of claim 16, wherein the providing of the preliminary display device includes:
removing a release paper, in which a convex part is defined, from the cover panel.

18. The method of claim 17, wherein the cover panel includes a first area in which the at least one groove is defined and a second area around the first area,
the second area has a smaller thickness than a thickness a portion of the first area outside the at least one groove, and
a thickness of a portion of the release paper, which is attached to the second area of the cover panel, is greater than a thickness of a portion of the release paper, which is attached to the portion of the first area of the cover panel outside the at least one groove.

19. The method of claim 18, wherein a sum of the thicknesses of the cover panel and the release paper is constant.

20. The method of claim 16, wherein the providing of the preliminary display device includes:
preparing a preliminary cover panel;
arranging a jig, in which a convex part is formed, on a rear surface of the preliminary cover panel;
forming the cover panel, in which the at least one groove is defined, by pressing the jig to the preliminary cover panel; and
attaching the cover panel, the display panel, and the printed circuit board electrically connected to the display panel.
